(19) United States
(12) Patent Application Publication
(10) Pub. No.: US 2008/0176377 A1
(43) Pub. Date: Jul. 24, 2008

(54) METHOD OF MANUFACTURING SEMICONDUCTOR DEVICE

(75) Inventor: Kazuo YAMAZAKI, Tokyo (JP)

Correspondence Address: SUGHRUE MION, PLLC, 2100 PENNSYLVANIA AVENUE, N.W., SUITE 800, WASHINGTON, DC, 20037, US

(73) Assignee: ELPIDA MEMORY, INC., Tokyo (JP)

(21) Appl. No.: 11/834,465

(22) Filed: Aug. 6, 2007

(30) Foreign Application Priority Data
Aug. 17, 2006 (JP) 2006-222237

(51) Int. Cl. H01L 21/762

(52) U.S. Cl. 438/424; 257/E21.545

(57) ABSTRACT

A method of manufacturing a semiconductor device in accordance with the present invention comprises the steps of:
(a) forming a gate (21) provided with side walls (12 to 14), in which each lower surface of the side walls is in contact with the surface of a substrate (1) through a first insulating film (13), on the substrate (1);
(b) selectively forming an epitaxial film (31) on a diffusion region (41) within substrate (1) between adjacent gates (21);
(c) forming a second insulating film (32 & 33) on an element-isolating region (42) adjacent to the diffusion regions (41); and
(d) forming a conductor (11) on the epitaxial film (31) provided on the diffusion region (41) by processing a conductive film into a columnar form, wherein the step (c) includes (c1) forming the second insulating film (32 & 33) so that the thickness thereof is larger than that of a first insulating film (13).

### BACKGROUND OF THE INVENTION

1. Field of the Invention

The present invention relates to a method of manufacturing a semiconductor device and, more particularly, to a manufacturing method for forming a plurality of pads made of conductors between wiring lines.

2. Related Art

As a method of forming contacts between gate layers of an MOS transistor, there is known a method of performing self-aligned contact (SAC) process-based oxide film etching upon gate wiring. However, as the gate-to-gate distance decreases with an advance in the miniaturization of devices, it has become increasingly difficult to simultaneously achieve both the openability of holes during oxide film hole etching and etching selectivity between oxide film and nitride film on the gate wiring. Accordingly, an approach is taken in the development of DRAMs subsequent to the introduction of the 0.08 μm process, toward newly introducing a method of forming contact portions using pads made by processing polysilicon into a columnar form.

FIGS. 1 and 2 are a schematic cross-sectional view and a schematic plan view, respectively, illustrating conventional contact portions. Here, FIG. 1 is a cross-section along the line AA′ of FIG. 2, illustrating a condition wherein after forming gates 121, polysilicon pads 111 are formed as contact portions by processing polysilicon into a columnar form. Note that although polysilicon pad 111 does not exist in the cross-section AA′ of FIG. 2, a shape corresponding to a cross-section of the polysilicon pad in the center thereof is indicated in FIG. 1 as polysilicon pads 111 by outlining the shape with a solid line without hatching, in order to show the shape of the polysilicon pads and their relative positional relationship with gates 121. Here, gate 121 includes silicon dioxide (SiO₂) thin film 110 provided on substrate 101, polysilicon film 117, tungsten silicide (WSi) film 119, tungsten nitride (WN) film 118, tungsten (W) film 116, silicon nitride (Si₃N₄) film 115, silicon nitride film 112, silicon dioxide film 113, silicon nitride film 114, and diffusion regions (not shown in the figure).

Silicon dioxide thin film 110 is a gate oxide film formed on the surface of substrate 101 or on the surface of the channel region of a well (not shown in the figure) provided within substrate 101. Polysilicon film 117 is a gate electrode formed on silicon dioxide thin film 110. Tungsten silicide film 119 and tungsten nitride film 118 are buffer layers for suppressing reaction and reducing contact resistance in a boundary surface between polysilicon film 117 and tungsten film 116 formed thereon. Silicon nitride film 115 is provided so as to cover tungsten film 116. Silicon nitride film 114 is provided so as to cover the side surfaces of silicon nitride film 115 and tungsten film 116. Silicon dioxide film 113 is provided so as to cover the side surfaces of silicon nitride film 115, tungsten film 116 and polysilicon film 117 and the surfaces of substrate 101 at the ends of the channel region. Silicon nitride film 112 is provided so as to cover the side surfaces and the upper surface of silicon dioxide film 113. Silicon nitride film 114, silicon nitride film 112 and silicon dioxide film 113 form the side walls of gate 121. The diffusion regions (not shown in the figure) are provided in the vicinity of the surface of substrate 101 to form the source and drain electrodes of an MOS transistor.

Note here that when depositing polysilicon film for forming polysilicon pad 111, parts of silicon dioxide films 113 below silicon nitride films 112 provided as side walls may in some cases be etched due to cleaning performed as pretreatment, thereby producing voids 151 below silicon nitride films 112. In this case, polysilicon films 131 come into the voids (ends of region P) when polysilicon film for polysilicon pad 111 is deposited. If this occurs, it is no longer possible to completely remove polysilicon films 131 in the voids by dry etching when processing polysilicon pads 111, thus resulting in etching residues. Consequently, adjacent polysilicon pads 111 are short-circuited by polysilicon films 131.

FIGS. 3 and 4 are a schematic cross-sectional view and a schematic plan view, respectively, illustrating conventional contact portions. Here, FIG. 3 is a cross-section along the line BB′ of FIG. 4, illustrating a condition wherein after forming gates 121, polysilicon pads 111 are formed as the contact portions. The configuration of the respective components of FIGS. 3 and 4 are the same as that of FIGS. 1 and 2.

Note here that the lower ends of the side surfaces of silicon nitride films 112 may in some cases be etched into a vertical form or an overhanging form when silicon nitride films 112 composing the side walls of gates 121 are formed using a dry etching process. In this case, if polysilicon films for polysilicon pads 111 are formed, polysilicon films 134 in the vertical or overhanging portions 154 are difficult to remove by dry etching when processing polysilicon pads 111, thus easily resulting in etching residues. Consequently, adjacent polysilicon pads 111 are short-circuited by polysilicon films 134.

Accordingly, there has been a desire for a technique to prevent short-circuiting between adjacent polysilicon pads.

As related art, Japanese Patent Laid-Open No. 2004-119644 discloses a semiconductor device and a method of manufacturing the semiconductor device. This method of manufacturing a semiconductor device comprising the steps of:

(a) preparing a semiconductor substrate having a first impurity region exposed in a main surface and having, on said main surface, a gate structure including a gate electrode provided with a first insulating film on a side part thereof;

(b) forming an epitaxial layer on said first impurity region so that said first insulating film lies between said epitaxial layer and said gate electrode;

(c) forming a second insulating film on a side part of said gate electrode and a whole upper surface of said epitaxial layer;

(d) forming an interlayer insulating film on an upper surface of a structure obtained by execution of said step (c);

(e) etching said interlayer insulating film using said second insulating film as an etching stopper, thereby forming, in said interlayer insulating film, a first contact hole reaching said second insulating film provided on said epitaxial layer, said second insulating film lying between said gate electrode and said first contact hole;

(f) etching said second insulating film exposed by execution of said step (e), thereby forming a second contact hole reaching said epitaxial layer in said second insulating film; and

(g) forming a contact plug to fill in said first and second contact holes.

### SUMMARY OF THE INVENTION

Accordingly, it is an object of the present invention to provide a method of manufacturing a semiconductor device capable of preventing short-circuiting between adjacent polysilicon pads.

It is another object of the present invention to provide a method of manufacturing a semiconductor device whereby it is possible to improve the production yield of semiconductor devices.

Hereinafter, a description will be made of means for solving problems using numerals and symbols used in the best mode for carrying out the invention. These numerals and symbols are appended enclosed in parentheses in order to clarify the correlation between the description of claims and the best mode for carrying out the invention. However, these numerals and symbols should not be used to interpret the technical scope of the invention as described in the appended claims.

In order to solve the aforementioned problems, a method of manufacturing a semiconductor device in accordance with the present invention comprises the steps of:

(a) forming a gate (21) provided with side walls (12, 13 and 14), in which each lower surface of the side walls is in contact with the surface of a substrate (1) through a first insulating film (13), on the substrate (1);

(b) forming an epitaxial film (31) on a diffusion region (41) within the substrate (1) between the adjacent gates (21);

(c) forming a second insulating film (32 and 33) to a thickness approximately the same as that of the epitaxial film (31), on an element-isolating region (42) adjacent to the diffusion region (41); and

(d) forming a conductor (polysilicon pad for contact) (11) on the epitaxial film (31) provided on the diffusion region (41) by processing a conductive film into a columnar form.

In the present invention, the second insulating film (32 and 33) is formed on the element-isolating region (42) prior to forming the polysilicon pad (11). This means that portions, such as voids (51) of the first insulating films (13) between adjacent gates (21) and overhangs of the lower ends of the side walls (12) where a conductive film is easy to remain, are previously covered by the second insulating film. This eliminates such a phenomenon that the conductive film for the polysilicon pad (11) remains in the voids (51) or in the overhangs due to insufficient etching even when the conductive film is formed later and etched into a columnar form. Thus, it is possible to prevent short-circuiting from occurring between the polysilicon pads (11). Note that the notion that the epitaxial film (31) is approximately the same as the second insulating film (32 and 33) in film thickness means that the film thickness need not necessarily be the same therebetween and a difference within a predetermined range is tolerated.

In the above-described method of manufacturing a semiconductor device, it is preferred that the step (b) comprises the step of (b1) forming the epitaxial film (31) so that the thickness thereof is larger than that of the first insulating film (13) and adjacent epitaxial films (31) do not come into direct contact with each other.

In the present invention, it is possible for the epitaxial film (31) and the second insulating film (32 and 33) to reliably cover the voids (51) formed by side-etching of the first insulating film (13) by making the thickness of the epitaxial film (31) larger than that of the first insulating film (13).

In the above-described method of manufacturing a semiconductor device, it is preferred that the step (c) comprises the step of (c1) forming the second insulating film (32 and 33) so that the thickness thereof is larger than that of the first insulating film (13).

In the present invention, it is possible to more reliably cover the voids (51) formed by side-etching of the first insulating films (13) by making the thickness of the second insulating film (32 and 33) larger than that of the first insulating film (13).

In the above-described method of manufacturing a semiconductor device, it is preferred that the step (b) comprises the step of (b2) forming the epitaxial film (31) so that the thickness thereof is larger than the height at which the lower ends of the side walls (12) overhang.

In the present invention, it is possible for the epitaxial film (31) and the second insulating film (32 and 33) to reliably cover the overhangs of the side walls (12, 13 and 14) by making the thickness of the epitaxial film (31) larger than the height at which the lower ends of the side walls (12) overhang.

In the above-described method of manufacturing a semiconductor device, it is preferred that the step (c) comprises the step of (c2) forming the second insulating film (32 and 33) so that the thickness thereof is larger than the height at which the lower ends of the side walls (12) overhang.

In the present invention, it is possible for the second insulating film (32 and 33) to reliably cover the overhangs of the side walls (12) by making the thickness of the second insulating film (32 and 33) larger than the height at which the lower ends of the side walls (12) overhang.

In the above-described method of manufacturing a semiconductor device, it is preferred that the step (c) comprises the steps of:

(c3) forming the second insulating film (32 and 33) so as to cover each side surface of the side walls (12), the surface of the epitaxial film (31) and the surface of the element-isolating region (42); and

(c4) performing etching so that the surface of the epitaxial film (31) is exposed above the diffusion region (41) and the second insulating film (32 and 33) remain on the element-isolating region (42).

In the present invention, it is possible to form the polysilicon pad (11) on the epitaxial film (31) by exposing the epitaxial film (31), as well as prevent the conductive film for the polysilicon pad (11) of contact portions from entering the voids (51) since the second insulating films (32 and 33) remain on the element-isolating region (42).

In the above-described method of manufacturing a semiconductor device, it is preferred that the step (c3) comprises the steps of:

(c31) forming a third insulating film (33) so as to cover each side surface of the side walls (12), the surface of the epitaxial film (31) and the surface of the element-isolating region (42); and

(c32) forming a fourth insulating film (32) so as to cover the surface of the third insulating film (33).

It is also preferred that the step (c4) comprises the steps of:

(c41) etching the fourth insulating film (32) so that on the diffusion region (41) the surface of the third insulating film (33) is exposed and on said element-isolating region the height of the fourth insulating film (32) equals the surface height of the third insulating film (33); and

(c42) etching the third insulating film (33) so that the surface of the epitaxial film (31) is exposed.

In the present invention, it is possible to use the third insulating film (33) as an etching stopper in the step (c41) since the second insulating film (32 and 33) is a two-layered film formed of the third insulating film (33) and the fourth insulating film (32).

In the above-described method of manufacturing a semiconductor device, the fourth insulating film (32) is an oxide film formed using a material having a high degree of reflowability. It is preferred that the step (c32) comprises the step of (c321) reflowing the fourth insulating film (32) to approximately planarize the surface thereof with respect to the surface of the substrate (1).

In the present invention, it is possible to make it easy to control the amount of the forth insulating film (32) to be etched off by planarizing the surface of the fourth insulating film (32).

In the above-described method of manufacturing a semiconductor device, it is preferred that the step (c41) comprises the step of (c411) removing the fourth insulating film (32) by wet etching.

In the present invention, it is possible to make it easy to control the amount of the forth insulating film (32) to be etched off by wet etching since the surface of the fourth insulating film (32) is planarized.

According to the present invention, it is possible to prevent short-circuiting between adjacent polysilicon pads in a semiconductor device.

### BRIEF DESCRIPTION OF THE DRAWINGS

FIG. 1 is a schematic cross-sectional view illustrating conventional contact portions;

FIG. 2 is a schematic plan view illustrating conventional contact portions;

FIG. 3 is another schematic cross-sectional view illustrating conventional contact portions;

FIG. 4 is another schematic plan view illustrating conventional contact portions;

FIG. 5 is a schematic plan view illustrating the configuration of an exemplary embodiment of a semiconductor device manufactured using a method of manufacturing a semiconductor device in accordance with the present invention;

FIG. 6 is a schematic view illustrating the cross-section AA′ of the semiconductor device shown in FIG. 5;

FIG. 7 is a schematic view illustrating the cross-section BB′ of the semiconductor device shown in FIG. 5;

FIG. 8 is a cross-sectional view illustrating the condition of a semiconductor device in a process of an exemplary embodiment of the method of manufacturing a semiconductor device in accordance with the present invention;

FIG. 9 is a plan view of the semiconductor device shown in FIG. 8;

FIG. 10 is another cross-sectional view illustrating the condition of a semiconductor device in a process of an exemplary embodiment of the method of manufacturing a semiconductor device in accordance with the present invention;

FIG. 11 is a plan view of the semiconductor device shown in FIG. 10;

FIG. 12 is yet another cross-sectional view illustrating the condition of a semiconductor device in a process of an exemplary embodiment of the method of manufacturing a semiconductor device in accordance with the present invention;

FIG. 13 is a plan view of the semiconductor device shown in FIG. 12;

FIG. 14 is a cross-sectional view of the semiconductor device shown in FIG. 12;

FIG. 15 is still another cross-sectional view illustrating the condition of a semiconductor device in a process of an exemplary embodiment of the method of manufacturing a semiconductor device in accordance with the present invention;

FIG. 16 is a plan view of the semiconductor device shown in FIG. 15; and

FIG. 17 is a cross-sectional view of the semiconductor device shown in FIG. 15.

### DETAILED DESCRIPTION OF THE PREFERRED EMBODIMENTS

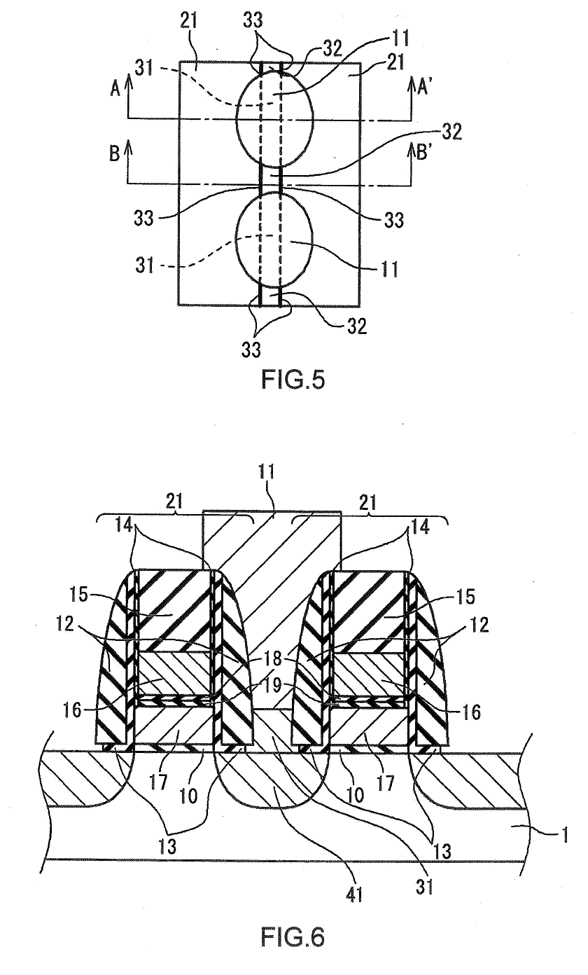

Hereinafter, exemplary embodiments of a method of manufacturing a semiconductor device in accordance with the present invention will be described with reference to the accompanying drawings. FIG. 5 is a schematic plan view illustrating the configuration of an exemplary embodiment of a semiconductor device manufactured using the method of manufacturing a semiconductor device in accordance with the present invention. In the description made hereinafter, although an example is shown wherein the present invention is applied between two gates 21 in the figure, the invention is likewise applied between another two gates 21. This semiconductor device comprises gates 21, polysilicon pads 11, silicon dioxide films 32 and silicon nitride thin films 33.

Gate 21 constitutes an MOS transistor, the details of which are explained later. Polysilicon pad 11 is a contact portion for connecting wiring lines with the source and drain electrodes of the MOS transistor and is made of polycrystalline silicon. Polysilicon pad 11 is formed on the diffusion regions (source and drain electrodes, which are not shown in the figure, will be explained later) of the MOS transistor.

Silicon dioxide film 32 and silicon nitride thin film 33 insulate adjacent polysilicon pads 11 from each other. Silicon dioxide film 32 and silicon nitride thin film 33 are provided on an element-isolating region (which is not shown in the figure and will be explained later) for separating adjacent polysilicon pads 11 from each other, i.e., separating MOS transistors from each other. Silicon nitride thin film 33 is provided between polysilicon pad 11 and silicon dioxide film 32, between gate 21 and silicon dioxide film 32, and between silicon dioxide film 32 and the element-isolating region, respectively. On silicon nitride thin film 33 and silicon dioxide film 32, there is formed an unillustrated interlayer insulating film in a region surrounded by polysilicon pads 11 and gates 21.

FIG. 6 is a schematic view illustrating the cross-section AA′ of the semiconductor device shown in FIG. 5. FIG. 6 shows a condition wherein after forming gates 21 and then selective epitaxial growth layer 31, silicon nitride thin films 33 and silicon dioxide films 32 (which are not shown in FIG. 6), polysilicon pad 11 is formed as contact portions by processing a conductive film made of polysilicon into a columnar form. This figure illustrates the relationship of gates 21, selective epitaxial growth layer 31 and polysilicon pad 11.

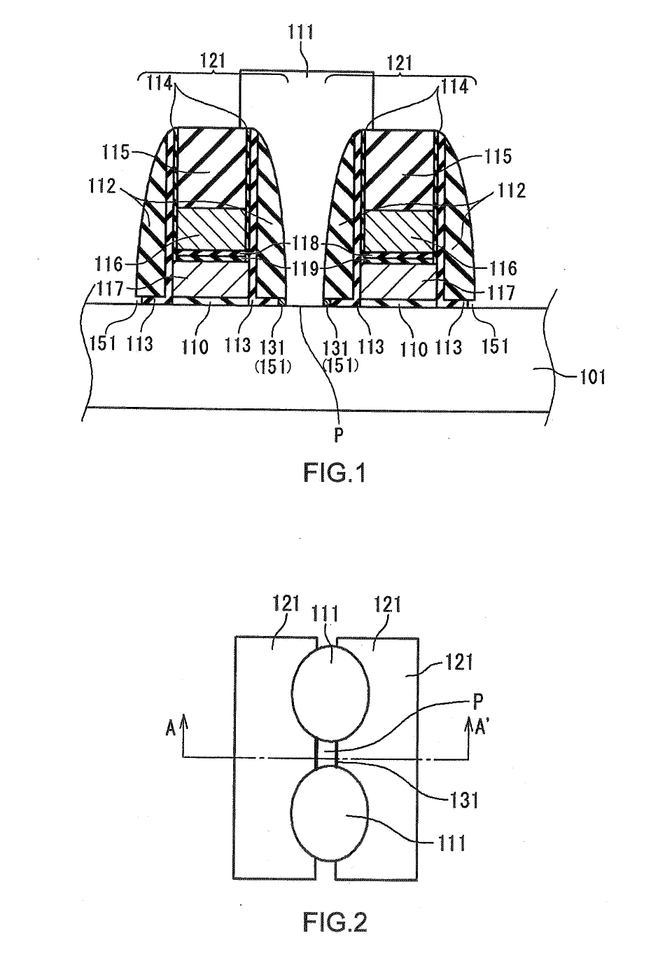

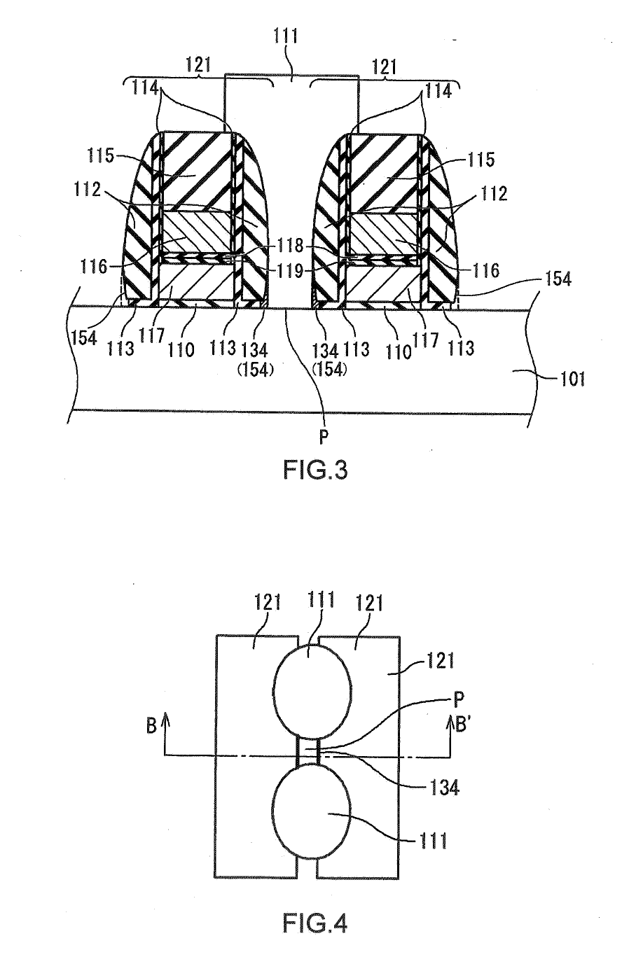

Gates 21 are the same as gates 121 shown in FIG. 1 and FIG. 3. In other words, gates 21 include silicon dioxide thin films 10 provided on substrate 1 as exemplified by silicon, polysilicon films 17, tungsten silicide films 19, tungsten nitride films 18, tungsten films 16, silicon nitride films 15, silicon nitride films 12, silicon dioxide films 13, and silicon nitride films 14.

Silicon dioxide thin film 10 is a gate oxide film formed on the surfaces of a channel region of wells (not shown in the figure) provided on or within substrate 1. Polysilicon film 17 is a gate electrode formed on silicon dioxide thin film 10. Diffusion regions 41 are source and drain electrodes provided on both side of the channel region in the vicinity of the surface of substrate 1. In other words, silicon dioxide thin film 10, polysilicon film 17 and diffusion regions 41 constitute an MOS transistor.

Tungsten silicide film 19 and tungsten nitride film 18 are buffer layers for suppressing reaction and reducing contact resistance at a boundary surface between polysilicon film 17 and tungsten film 16 formed thereon. Silicon nitride film 15 is provided so as to cover tungsten film 16. Silicon nitride films 14 are provided so as to cover the side surfaces of silicon nitride film 15 and tungsten film 16. Silicon dioxide films 13 are provided so as to cover, via silicon nitride films 14, the side surfaces of silicon nitride film 15 and tungsten film 16, the side surfaces of polysilicon film 17, and the surface of substrate 1 at the ends of a channel region. Silicon nitride films 12 are provided so as to cover the side surfaces and the upper surface of silicon dioxide films 13. Silicon nitride films 14, silicon dioxide films 13 and silicon nitride films 12 form the side walls of gate 21.

Selective epitaxial growth layer 31 connects polysilicon pad 11 with diffusion region 41 and is a silicon film formed by selective epitaxial growth from the silicon surface of diffusion region 41. The selective epitaxial growth layer is grown only on diffusion region 41 and is not grown on an element-isolating region (STI (Shallow Trench Isolation)-buried oxide film, which will be explained later).

It is preferred that the film thickness of selective epitaxial growth layer 31 be at least larger than the thickness (5 to 15 nm, typically 10 nm) of silicon dioxide film 13 below silicon nitride film 12. The reason for this is to make the heights of silicon nitride thin film 33 and silicon dioxide film 32 larger from the surface of substrate 1 than the thickness of silicon dioxide film 13, in order to be able to prevent polysilicon films 131 shown in FIG. 1 from being formed, as described later.

In addition, it is preferred that the film thickness of selective epitaxial growth layer 31 be larger than the thickness of a region where polysilicon films 134 shown in FIG. 3 are easy to be produced as etching residues when polysilicon pad 11 is etched. The reason for this is to make the heights of silicon nitride thin film 33 and silicon dioxide film 32 from the surface of substrate 1 larger than the thickness of the region where polysilicon films 134 are easy to be produced, in order to be able to prevent polysilicon films 134 shown in FIG. 3 from being formed, as described later. In other words, both of silicon nitride thin film 33 and silicon dioxide film 32 are preferably at least 20 nm thick and, more preferably, at least 30 nm thick from the surface of substrate 1.

On the other hand, as the film being epitaxially grown becomes thicker, the frequency of irregular growth in which silicon grows on silicon nitride film 12 increases due to the degradation of selectivity. In addition, there takes place short-circuiting between epitaxially grown portions if the grown film thickness is too large since epitaxial growth involves not only directly upward growth but also horizontal growth. For this reason, the grown film thickness is preferably 100 nm or so at the most and, more preferably, 50 nm or less.

Polysilicon pad 11 connects the diffusion region 41 of the MOS transistor with an upper wiring line (not shown in the figure) via selective epitaxial growth layer 31.

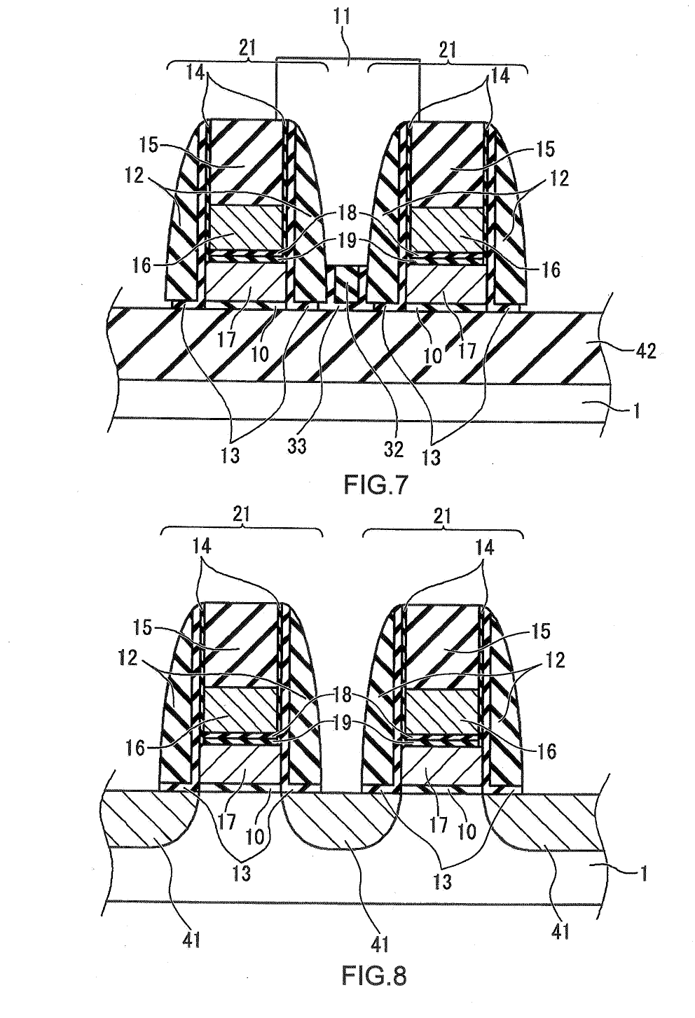

FIG. 7 is a schematic view illustrating the cross-section BB′ of the semiconductor device shown in FIG. 5. Like FIG. 6, FIG. 7 shows a condition wherein polysilicon pad 11 as contact portions is formed after forming gates 21 and then selective epitaxial growth layer 31 (not present in the cross-section BB′), silicon nitride thin film 33 and silicon dioxide film 32. Note that since polysilicon pad 11 does not exist in the cross-section BB′, the pad is shown in FIG. 7 as a shape outlined by a solid line without hatching.

This figure illustrates a structure formed on element-isolating region 42 (STI-buried oxide film) for electrically isolating the MOS transistors. This figure illustrates the relationship of gates 21, silicon nitride thin films 33 and silicon dioxide films 32. Gates 21 are as shown in FIG. 6.

Silicon nitride thin films 33 are provided so as to cover the surface of element-isolating region 42 and the lower ends of the side surfaces of silicon nitride films 12 between adjacent gates 21. Silicon nitride thin films 33 are formed in order to prevent silicon dioxide thin films 13 (lower ends of gates 21) of the side walls of gates 21 from being etched, as described later, when wet-etching silicon dioxide films 32. Preferably, the thickness of silicon nitride thin films 33 is 10 to 20 nm. The lower limit of the thickness is the minimum film thickness controllable. The upper limit of the thickness is a film thickness at which it is easy (for example, only a short length of etching time is required or easy to control in terms of etching conditions) to expose the surface of epitaxially grown silicon by subsequent etching.

In conjunction with silicon nitride thin films 33, silicon dioxide films 32 cover the partially etched portions of silicon dioxide thin films 13 (lower ends of silicon nitride films 12) and overhangs at the lower ends of the side surfaces of silicon nitride films 12. By previously covering such portions as described above where polysilicon films 131 shown in FIG. 1 and polysilicon films 134 shown in FIG. 3 are easy to remain, it is possible to prevent polysilicon film for polysilicon pad 11 from being formed in the abovementioned portions. Consequently, it is possible to prevent polysilicon films 131 shown in FIG. 1 and polysilicon films 134 shown in FIG. 3 from being produced, thereby preventing short-circuiting between polysilicon pads 11. As described later, the thickness of silicon dioxide film 32 is approximately the same as the film thickness of selective epitaxial growth layer 31. The reason for this is to use a method of forming contact portion (polysilicon pad 11) by processing polysilicon into a columnar form.

Next, a description will be made of an exemplary embodiment of a method for manufacturing the semiconductor device of the present invention. FIGS. 8 to 17 are either a plan view or a cross-sectional view illustrating the condition of a semiconductor device in each process of the exemplary embodiment of the method for manufacturing the semiconductor device of the present invention. While an explanation will be made here with regard to a case where silicon dioxide film 13 at the lower ends of silicon nitride film 12 is etched partially, the same explanation is likewise applicable to a case where the lower end of the side surface of silicon nitride film 12 has an overhanging form.

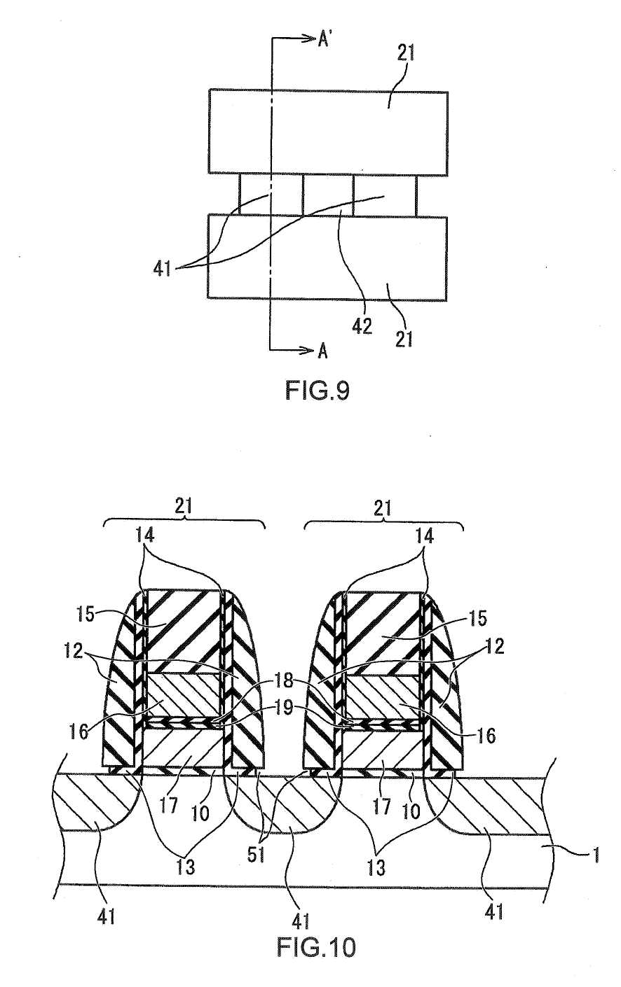

FIG. 8 shows a cross-sectional view of an in-process semiconductor device in a condition wherein gates 21 are formed on substrate 1. The configuration of gates 21 is as described earlier. Since gates 21 can be produced using a known method, the method will not be explained here. FIG. 9 is a plan view of the semiconductor device shown in FIG. 8. Note that FIG. 8 shows the cross-section AA′ of FIG. 9. Diffusion region 41 and element-isolating region 42 are alternately exposed between adjacent gates 21.

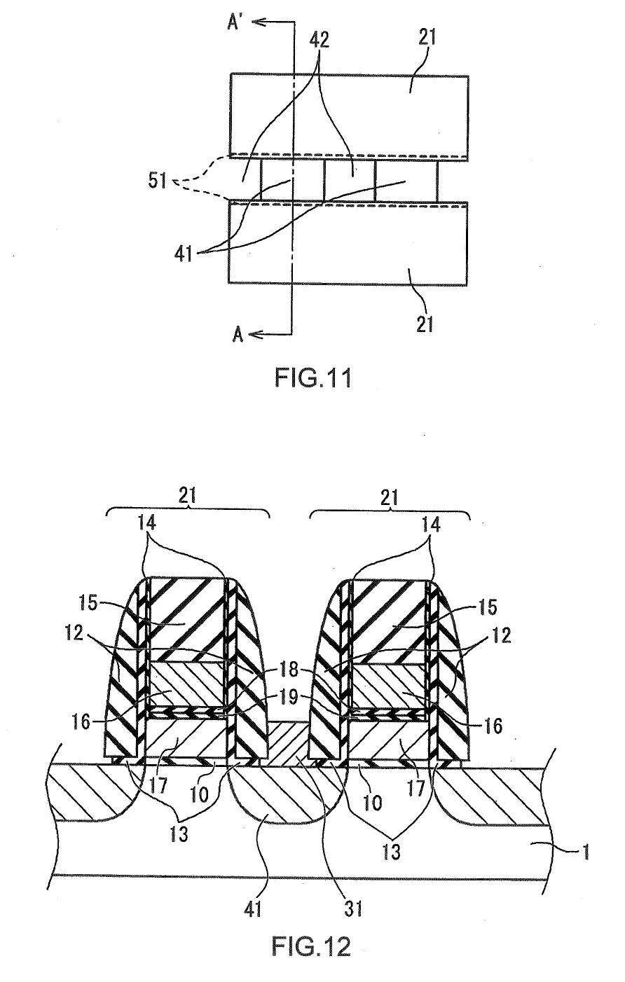

In the condition shown in FIGS. 8 and 9, the edges of silicon dioxide films 13 below silicon nitride films 12 of side walls may in some cases be etched partially when, for example, substrate 1 is immersed in a cleaning solution for cleaning. Such a condition is illustrated in FIG. 10. FIG. 10 shows a cross-section of an in-process semiconductor device after immersion in a cleaning solution. The edges of silicon dioxide films 13 are etched and thus voids 51 are formed. FIG. 11 is a plan view of the semiconductor device shown in FIG. 10. Voids 51 are formed so as to connect adjacent diffusion regions 41. In this case, there will results such a situation as shown in FIG. 1 or FIG. 2 if the manufacturing of the semiconductor device is continued using a conventional method. In addition, in a case where the side surfaces of silicon nitride film 12 of the side walls are over-etched, though not shown in the figure, there will result such situations as shown in FIG. 3 and FIG. 4 if the manufacturing of the semiconductor device is continued using a conventional method. Note that FIG. 10 is the cross-section AA′ of FIG. 11.

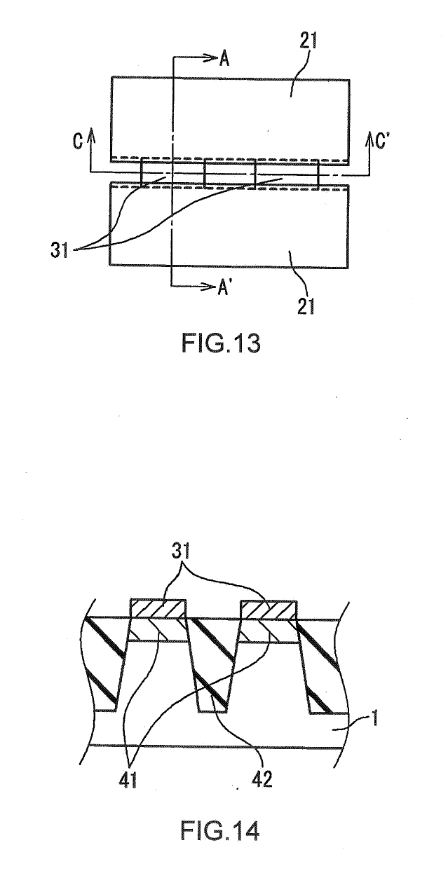

First, from the condition shown in FIGS. 10 and 11, a selective epitaxial growth layer 31 of silicon is grown on diffusion region 41 by selective epitaxial growth. As a method of this selective epitaxial growth, there is applied a low-pressure CVD process using a mixed gas of, for example, SiH₂Cl₂, H₂ and HCl as the raw material to achieve the epitaxial growth under a pressure of 50 Torr and a substrate temperature of 850° C. The upper and lower limits of the film thickness of selective epitaxial growth layer 31 are as described earlier, where the film thickness is typically 40 nm. Such a condition as described above is illustrated in FIG. 12. FIG. 12 shows a cross-sectional view of an in-process semiconductor device after the growth of selective epitaxial growth layer 31. Selective epitaxial growth layer 31 is formed on diffusion region 41. FIG. 13 is a plan view of the semiconductor device shown FIG. 12. Selective epitaxial growth layer 31 is formed on diffusion region 41 so as to fill voids 51 on diffusion region 41. Note that FIG. 12 is the cross-section AA′ of FIG. 13. FIG. 14 is the cross-section CC′ of FIG. 13. Whereas selective epitaxial growth layers 31 are formed on diffusion regions 41, no layer is formed on element-isolating region 42. In other words, selective epitaxial growth layers 31 are grown only on substrate 1 made of silicon which is diffusion regions 41 and are not grown on element-isolating region 42 (STI-buried oxide film).

Next, from the condition shown in FIGS. 12 to 14, silicon nitride thin film 33 is formed on the entire surface of the semiconductor device so as to cover the surfaces of gates 21, selective epitaxial growth layers 31 and element-isolating regions 42. As a method of this film formation, there is applied a low-pressure CVD process using a mixed gas of, for example, SiH₂Cl₂ and NH₃ as the raw material to achieve the film formation under a pressure of 2 Torr and a temperature of 680° C. Note here that silicon nitride thin film 33 is formed in order to prevent silicon dioxide films 13 of the side walls of gates 21 from being etched when wet-etching silicon dioxide film 32 (explained later). Then, silicon dioxide film 32 is formed so as to cover silicon nitride thin film 33. Suitably, the silicon dioxide film has a high degree of reflowability. For example, the silicon dioxide film is of such a type that after forming a film of polysilazane (inorganic Spin On Glass (SOG)), the film surface is planarized by steam treatment, of such a type that after forming a film of boro-phospho silicate glass (BPSG), the film surface is planarized by annealing treatment, or of such a type that after forming a film of O₃-TEOS (tetraethoxy silane), the film surface is planarized by annealing treatment. As a method of forming the BPSG film, a mixed gas of, for example, TEOS, TEPO (tetraethoxy phosphate), TEB (tetraethoxy borate), O₂ and O₃ is used under a pressure of 600 Torr and a temperature 480° C. Likewise, as a method of forming the O₃-TEOS film, a mixed gas of, for example, O₃ and TEOS is used under a pressure of 600 Torr and a temperature of 540° C.

Then, silicon dioxide film 32 is etched using a wet-etching liquid for a silicon dioxide film, such as a diluted hydrofluoric acid (HF) solution. As the condition of this etching, an etching liquid having a concentration of HF: H₂O=1:100 is used. Note that for an etching time, samples are created by varying the etching time and the optimum length of time is determined from the results of cross-sectional SEM observation. The amount of etching is set so that the surface of silicon nitride thin film 33 on selective epitaxial growth layer 31 show up across the entire surface of a wafer. As a result, the total thickness (height from the surface of substrate 1) of silicon nitride thin film 33 and silicon dioxide film 32 is approximately the same as that of selective epitaxial growth layer 31 and silicon nitride thin film 33 combined. In other words, the thickness of silicon dioxide film 32 is approximately the same as that of selective epitaxial growth layer 31.

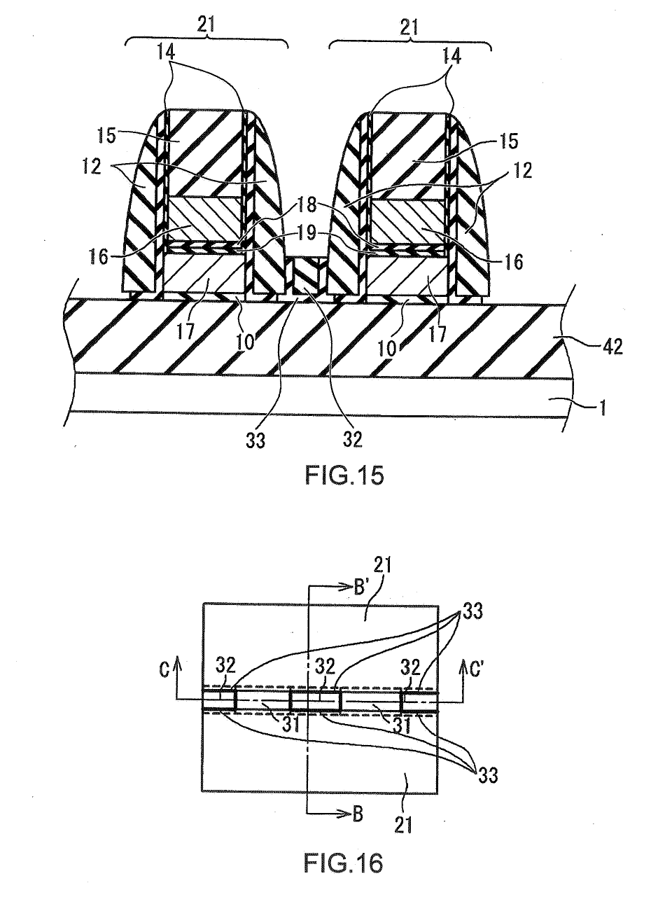

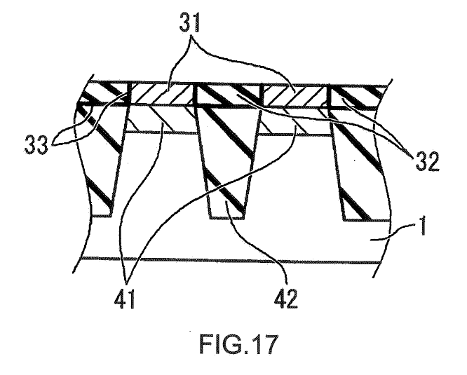

Then, silicon nitride thin film 33 is etched back to expose the surfaces of selective epitaxial growth layers 31 grown by selective epitaxial growth. As a method of this etching back, a parallel plate type RIE apparatus, for example, is used to perform the etching back using a mixed gas of CF₄, CHF₃, Ar and O₂ under a pressure of 40 mTorr and an RF power of 300 W. Such a condition as described above is illustrated in FIG. 15. FIG. 15 shows a cross-sectional view of an in-process semiconductor device after silicon dioxide film 32 and silicon nitride thin film 33 are etched. Silicon nitride thin film 33 and silicon dioxide film 32 are formed on element-isolating region 42. As a result, the surface height of selective epitaxial growth layer 31 is by as much as the thickness of silicon nitride thin film 33 smaller than the surface height of silicon dioxide film 32. However, the surface height (film thickness) of selective epitaxial growth layer 31 is approximately the same as that of silicon dioxide film 32 if silicon nitride thin film 33 is extremely thin. The notion that the film thickness of selective epitaxial growth layer 31 is approximately the same as that of silicon nitride thin film 33 and silicon dioxide film 32 combined means that the film thickness need not necessarily be the same between these two films and a difference within a predetermined range, for example, ±50% is tolerated. This range does not affect the method of forming the contact portions (polysilicon pads 11) by processing polysilicon into a columnar form. FIG. 16 is a plan view of the semiconductor device shown in FIG. 15. Silicon nitride thin films 33 and silicon dioxide films 32 are formed in element-isolating region 42, so as to fill voids 51 thereon. Note that FIG. 15 is the cross-section BB′ of FIG. 16. FIG. 17 is the cross-section CC′ of FIG. 16. Silicon nitride thin films 33 and silicon dioxide films 32 are formed on element-isolating regions 42, whereas selective epitaxial growth layers 31 are formed on diffusion regions 41.

Then, in the condition shown in FIGS. 15 to 17, polysilicon for forming polysilicon pad 11 is formed on the entire surface of the semiconductor device, so as to cover the surfaces of gates 21, selective epitaxial growth layers 31, silicon nitride thin films 33 and silicon dioxide films 32. As a method of this film formation, there is applied a low-pressure CVD process using, for example, SiH₄ as the raw material gas to perform the film formation under a pressure of 9 Torr and a temperature of 530° C. Next, after forming a resist pattern by photolithography, polysilicon pads 11 are formed by processing polysilicon into a columnar form by dry etching. As a method of this etching, a microwave etching apparatus, for example, is used to perform the etching using a mixed gas of HBr and O₂ under a pressure of 30 mTorr, a microwave power of 500 W and an RF power of 50 W. At this point, selective epitaxial growth layers 31 or silicon nitride thin films 33 and silicon dioxide films 32 are formed below a space between gates 21. Therefore, no etching residues are produced in overhangs below silicon nitride films 12 of the side walls of gates 21 and at the lower ends of the side walls of silicon nitride thin films 33 and silicon dioxide films 32. Consequently, it is possible to prevent short-circuiting between polysilicon pads 11.

Subsequently, by forming an interlayer insulating film between polysilicon pads 11, there is manufactured such a semiconductor device as shown in FIGS. 5 to 7.

According to the present invention, since a space between gates 21 is filled with insulating silicon nitride thin films 33 and silicon dioxide films 32, such short-circuiting between polysilicon pads 11 as shown in FIGS. 1 and 2 no longer takes place even if silicon dioxide films 13 below silicon nitride films 12 of side walls are etched to form voids 51. Although there is a possibility that selective epitaxial growth layers 31 also grow below silicon nitride films 12, this does not lead to short-circuiting between polysilicon pads 11 since such growth is limited to within diffusion region 41.

Furthermore, according to the present invention, since overhangs at the lower ends of side walls formed of silicon nitride films 12 are buried by selective epitaxial growth layers 31, silicon nitride thin films 33 and silicon dioxide films 32, such etching residues of polysilicon for polysilicon pad 11 as shown in FIGS. 3 and 4 are not produced. Consequently, short-circuiting between polysilicon pads 11 no longer takes place.

The present invention is applicable to such a step, in a process for forming a contact between wiring lines, wherein a method of contact formation is such that after forming a conductive film, columnar conductors are formed by etching. The conductive film is not limited to a polysilicon film but may be, in the alternative, a film of metal such as tungsten. Furthermore, the material below the contact is not limited to a silicon substrate but may be a polysilicon substrate.

It is apparent that the present invention is not limited to the above-described exemplary embodiments, but may be modified and changed as appropriate within the technical scope of the present invention.

What is claimed is:

1. A method of manufacturing a semiconductor device comprising the steps of:
(a) forming a gate provided with side walls, in which each lower surface of the side walls is in contact with the surface of a substrate through a first insulating film, on said substrate;
(b) forming an epitaxial film on a diffusion region within said substrate between the adjacent gates;
(c) forming a second insulating film to a thickness approximately the same as that of said epitaxial film, on an element-isolating region adjacent to said diffusion region; and
(d) forming a conductor on said epitaxial film provided on said diffusion region by processing a conductive film into a columnar form.

2. The method of manufacturing a semiconductor device according to claim 1,
wherein said step (b) comprises the step of (b1) forming said epitaxial film so that the thickness thereof is larger than that of said first insulating film and adjacent epitaxial films do not come into direct contact with each other.

3. The method of manufacturing a semiconductor device according to claim 2,
wherein said step (c) comprises the step of (c1) forming said second insulating film so that the thickness thereof is larger than that of said first insulating film.

4. The method of manufacturing a semiconductor device according to claim 2,
wherein said step (b) comprises the step of (b2) forming said epitaxial film so that the thickness thereof is larger than the height at which the lower ends of said side walls overhang.

5. The method of manufacturing a semiconductor device according to claim 4,
wherein said step (c) comprises the step of (c2) forming said second insulating film so that the thickness thereof is larger than the height at which the lower ends of said side walls overhang.

6. The method of manufacturing a semiconductor device according to claim 1,
wherein said step (c) comprises the steps of:
(c3) forming said second insulating film so as to cover the side surfaces of said side walls, the surface of said epitaxial film and the surface of said element-isolating region; and
(c4) performing etching so that the surface of said epitaxial film is exposed above said diffusion region and said second insulating film remains on said element-isolating region.

7. The method of manufacturing a semiconductor device according to claim 6,
wherein said step (c3) comprises the steps of:
(c31) forming a third insulating film so as to cover each side surface of said side walls, the surface of said epitaxial film and the surface of said element-isolating region; and
(c32) forming a fourth insulating film so as to cover the surface of said third insulating film, and
wherein said step (c4) comprises the steps of:
(c1) etching said fourth insulating film so that on said diffusion region the surface of said third insulating film is exposed, and on said element-isolating region the height of said fourth insulating film equals the surface height of said third insulating film provided on said diffusion region; and
(c42) etching said third insulating film so that the surface of said epitaxial film is exposed.

8. The method of manufacturing a semiconductor device according to claim 7,
wherein said fourth insulating film is an oxide film formed using a material having a high degree of reflowability and said step (c32) comprises the step of (c321) reflowing said fourth insulating film to approximately planarize the surface thereof with respect to the surface of said substrate.

9. The method of manufacturing a semiconductor device according to claim 8,
wherein said step (c41) comprises the step of (c411) removing said fourth insulating film by wet etching.
